(19) United States
(12) Patent Application Publication
(10) Pub. No.: US 2016/0145094 A1
(43) Pub. Date: May 26, 2016

(54) MICRO-ELELCTRO-MECHANICAL SYSTEM DEVICE AND METHOD FOR FABRICATING THE SAME

(71) Applicant: uPI Semiconductor Corp., Hsinchu County (TW)

(72) Inventors: Yueh-Kang Lee, Hsinchu County (TW); Li-Yeat Chen, Hsinchu County (TW); Yi-Chaio Lan, Hsinchu County (TW)

(21) Appl. No.: 14/741,471

(22) Filed: Jun. 17, 2015

(30) Foreign Application Priority Data
Nov. 20, 2014 (TW) 103140244

(51) Int. Cl. B81B 7/00; B81C 1/00

(52) U.S. Cl. CPC B81B 7/007; B81C 1/00301; B81B 2207/095

(57) ABSTRACT

A method for fabricating a micro-electro-mechanical system (MEMS) device includes following steps. A cap layer is formed on an MEMS structure. The MEMS structure has a plurality of sacrificial structures. The cap layer has a plurality of release holes. The release holes are located on the sacrificial structures. A dielectric layer is formed on the cap layer, and the dielectric layer fills the release holes. A planarization process is performed on the dielectric layer. The sacrificial structures are then removed to form at least one cavity in the MEMS structure.

### CROSS-REFERENCE TO RELATED APPLICATION

This application claims the priority benefit of Taiwan application serial no. 103140244, filed on Nov. 20, 2014. The entirety of the above-mentioned patent application is hereby incorporated by reference herein and made a part of this specification.

### FIELD OF THE INVENTION

The invention relates to an electronic device and a method for fabricating the same. More particularly, the invention relates to a micro-electro-mechanical system (MEMS) device and a method for fabricating the same.

### DESCRIPTION OF RELATED ART

A micro-electro-mechanical system (MEMS) device is an industrial technique combining micro-electronic technology and mechanical engineering. The MEMS device may include tiny electromechanical devices (e.g., switches, mirror surfaces, capacitors, accelerometers, sensors, capacitance sensors, actuators, and so on), and these electromechanical devices and integrated circuits may be integrated into one chip. However, in general, the MEMS device in the entire package structure is fragile and may be affected and impaired by static electricity or surface tension. Hence, to protect the MEMS device from pollution or damages, the MEMS device is often sealed between the chip and an ex-situ cap.

Nevertheless, using the ex-situ cap to protect the MEMS device may raise packaging difficulties. Besides, even though the ex-situ cap is employed to protect the MEMS device, the yield of the resultant device may not be satisfactory due to the insufficient mechanical strength of the hollow MEMS structure while a planarization process is performed.

### SUMMARY OF THE INVENTION

The invention is directed to a micro-electro-mechanical system (MEMS) device and a method for fabricating the same, whereby a process for manufacturing an ex-situ cap is no longer required, a chip area can be reduced, and manufacturing costs can be lowered down accordingly.

The invention is directed to an MEMS device and a method for fabricating the same, whereby the mechanical strength of the resultant MEMS device is improved, and the manufacturing yield can be improved as well.

The invention is directed to an MEMS device and a method for fabricating the same; the height and the thickness of the resultant MEMS device are both reduced, and therefore the flexibility of the packaging process can be improved.

In an embodiment of the invention, a method for fabricating an MEMS device includes following steps. An MEMS structure is formed on a substrate. The MEMS structure has at least one cavity therein. A first dielectric layer that covers the MEMS structure is formed, and the first dielectric layer fills the at least one cavity. A cap layer is formed on the first dielectric layer. The cap layer has a plurality of release holes located on the MEMS structure. A second dielectric layer is formed on the cap layer. The second dielectric layer fills the release holes. A planarization process is formed on the second dielectric layer to form a planarized second dielectric layer. The first dielectric layer is still located on the MEMS structure and in the at least one cavity. A release process is performed to remove the planarized second dielectric layer above the release holes and the first dielectric layer below the release holes.

According to an embodiment of the invention, before the MEMS structure is formed, the method further includes forming a stop layer on the substrate correspondingly located below the MEMS structure.

According to an embodiment of the invention, the method further includes forming a plurality of support structures in the MEMS structure, and the support structures are respectively connected to the cap layer and a conductive layer below the MEMS structure.

According to an embodiment of the invention, the release process includes an etching process. The etching process includes a vapor phase etching process, a liquid-phase etching process, or a combination thereof

According to an embodiment of the invention, after the release process is performed, the method further includes forming a sealing layer, and the sealing layer covers the MEMS structure.

According to an embodiment of the invention, before the release process is performed, the method further includes forming a conductive pad on the planarized second dielectric layer. The conductive pad is connected to the cap layer.

According to an embodiment of the invention, after the conductive pad is formed, the method further includes forming a passivation layer on the planarized second dielectric layer. The passivation layer covers a portion of the conductive pad. Besides, the passivation layer has an opening that exposes parts of the planarized second dielectric layer on the release holes.

According to an embodiment of the invention, a material of the passivation layer includes silicon nitride (SiN), titanium nitride (TiN), amorphous silicon, or a combination thereof.

According to an embodiment of the invention, the planarization process includes a chemical-mechanical polishing (CMP) process, an etch back process, or a combination thereof.

In an embodiment of the invention, an MEMS device that includes an MEMS structure, a periphery structure, a cap layer, a conductive pad, and a sealing layer is provided. The MEMS structure is located on a substrate. Besides, the MEMS structure has at least one cavity therein. The periphery structure is located on the substrate at one side of the MEMS structure. The cap layer is located on the MEMS structure and the periphery structure. The conductive pad is located on the cap layer in the periphery structure. The conductive pad is electrically connected to the periphery structure through the cap layer. The sealing layer covers the MEMS structure and a portion of the conductive pad.

According to an embodiment of the invention, the MEMS device further includes a plurality of support structures in the MEMS structure. The support structures are respectively connected to the cap layer and a conductive layer below the MEMS structure.

According to an embodiment of the invention, a material of the support structures includes doped polysilicon, undoped polysilicon, single crystalline silicon, or a combination thereof.

According to an embodiment of the invention, the MEMS device further includes a passivation layer that covers a portion of the conductive pad, and the passivation layer is located between the conductive pad and the sealing layer.

According to an embodiment of the invention, a material of the passivation layer includes SiN, TiN, amorphous silicon, or a combination thereof.

According to an embodiment of the invention, a material of the MEMS structure includes doped polysilicon, undoped polysilicon, single-crystalline silicon, or a combination thereof

According to an embodiment of the invention, a material of the cap layer includes doped polysilicon, undoped polysilicon, single-crystalline silicon, or a combination thereof

According to an embodiment of the invention, a material of the sealing layer includes polymer, SiN, silicon oxide (SiO), or a combination thereof

In an embodiment of the invention, another method for fabricating an MEMS device includes following steps. A cap layer and a dielectric layer are sequentially formed on an MEMS structure. The MEMS structure has a plurality of sacrificial structures therein. The cap layer has a plurality of release holes located on the sacrificial structures. A planarization process is performed on the dielectric layer. The sacrificial structures are then removed to form at least one cavity in the MEMS structure.

According to an embodiment of the invention, the method further includes forming a sealing layer on the cap layer. The sealing layer fills the release holes of the cap layer to seal the MEMS structure.

According to an embodiment of the invention, the method further includes forming a plurality of support structures in the MEMS structure.

In view of the above, an in-situ cap layer in the MEMS device described herein allows the process for manufacturing an ex-situ cap to be omitted; thereby, the chip area can be reduced, and the costs can be lowered down accordingly. From another perspective, compared to the ex-situ cap, the in-situ cap layer described herein is conducive to the reduction of the thickness of the resultant MEMS device, such that the flexibility of the packaging process can be enhanced. Moreover, after the planarization process is performed, the MEMS structure is released; as such, the issue of the insufficient mechanical strength of the hollow MEMS structure can be prevented, and the defect of low yield of the resultant device can be remedied.

Several exemplary embodiments accompanied with figures are described in detail below to further describe the invention in details.

### BRIEF DESCRIPTION OF THE DRAWINGS

FIG. 1 A to FIG. 1J are schematic cross-sectional views illustrating a process for fabricating a micro-electro-mechanical system (MEMS) device according to an embodiment of the invention.

FIG. 2 is a schematic cross-sectional view of an MEMS device according to another embodiment of the invention.

### DETAILED DESCRIPTION OF DISCLOSED EMBODIMENTS

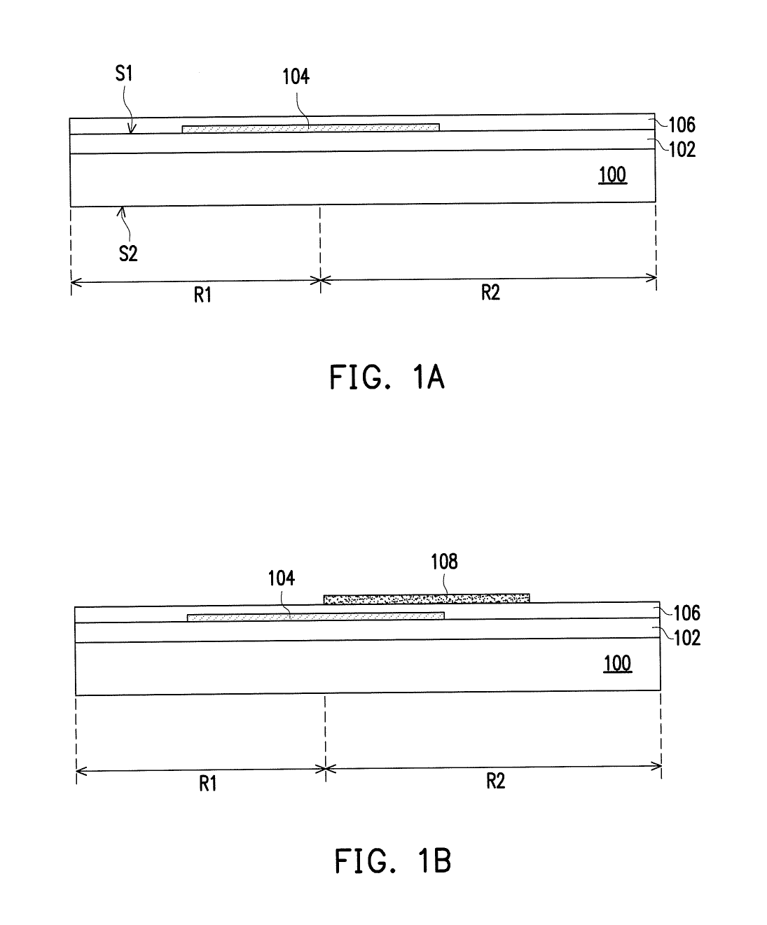

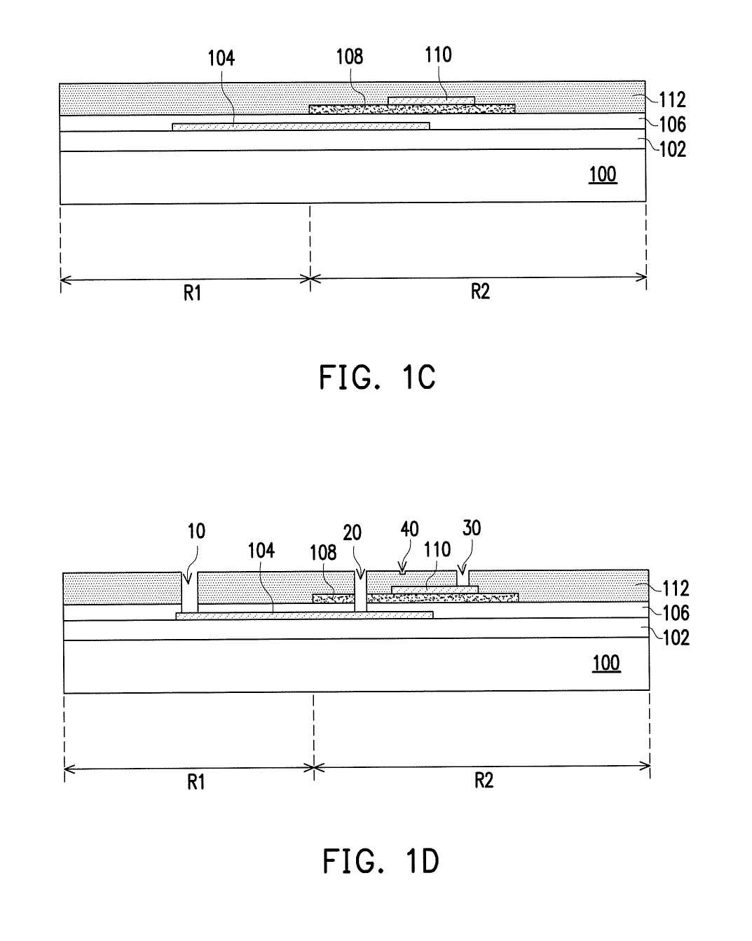

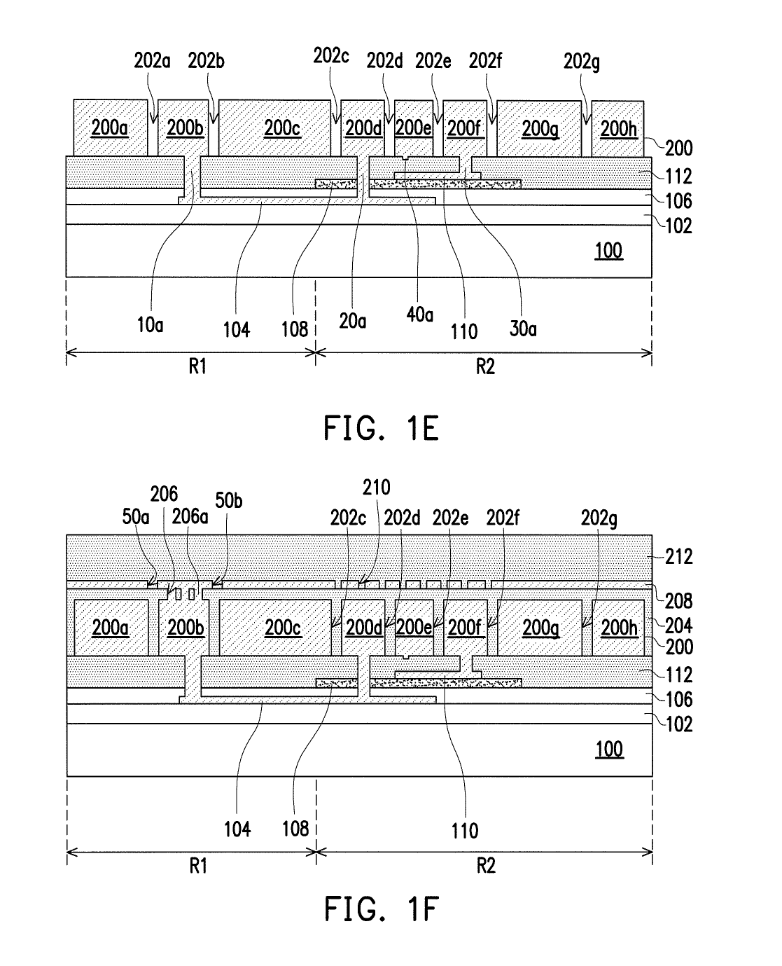

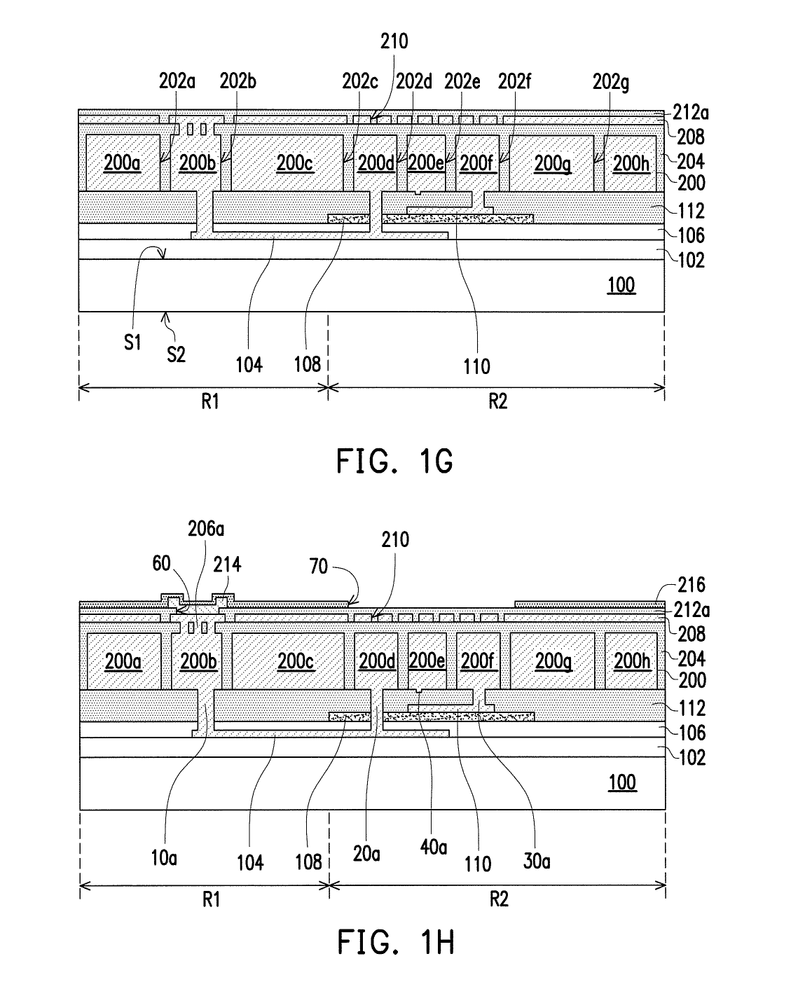

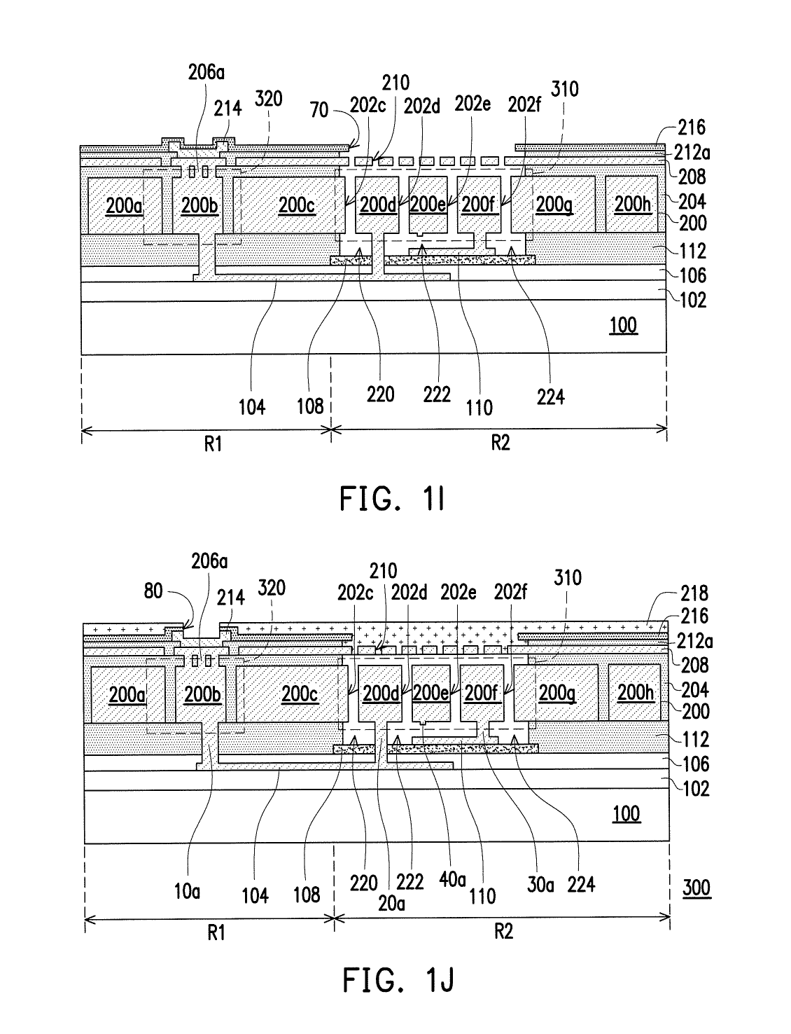

FIG. 1A to FIG. 1J are schematic cross-sectional views illustrating a process for fabricating a micro-electro-mechanical system (MEMS) device according to an embodiment of the invention.

With reference to FIG. 1A, in an embodiment of the invention, a method for fabricating an MEMS device includes following steps. First, a substrate 100 is provided. The substrate 100 is, for instance, a semiconductor substrate, a semiconductor compound substrate, or a semiconductor over insulator (SOI). The semiconductor is group IVA atoms, e.g., silicon or germanium. The semiconductor compound is, for instance, a semiconductor compound composed of group IVA atoms (e.g., silicon carbide or germanium silicon) or a semiconductor compound composed of group IIIA atoms and group VA atoms (e.g., gallium arsenide). The substrate 100 has a first region R1 and a second region R2. In the present embodiment, the first region R1 is, for instance, a periphery region, and the second region R2 is, for instance, a release region.

Thereafter, a dielectric layer 102, a conductive layer 104, and a dielectric layer 106 are sequentially formed on a front surface S1 of the substrate 100. The dielectric layer 106 covers a surface of the conductive layer 104 and a surface of the dielectric layer 102. In the present embodiment, the dielectric layer 102 is located on the substrate 100, and an electronic device having the dielectric layer 102 is less likely to encounter a feed-through issue. A material of the dielectric layer 102 and a material of the dielectric layer 106 are, for instance, silicon oxide (SiO), silicon nitride (SiN), or a combination thereof, and a method of forming the dielectric layers 102 and 106 includes, for instance, a chemical vapor deposition (CVD) method, a thermal oxidation method, and so forth. The conductive layer 104 covers a portion of the surface of the dielectric layer 102 and lies across the first region R1 and the second region R2. A method of forming the conductive layer 104 includes, for instance, forming a conductive material layer on the dielectric layer 102 and patterning the conductive material layer through performing a lithography and etching process. The conductive material layer may be, for example, doped polysilicon, undoped polysilicon, single-crystalline silicon, or a combination thereof, and the conductive material layer may be formed by performing a CVD process, for example.

With reference to FIG. 1B, a stop layer 108 is formed on the dielectric layer 106. The stop layer 108 is located on the dielectric layer 106 in the second region R2 and is partially overlapped with the conductive layer 104. The stop layer 108 may serve as an etch stop layer in a subsequent release process of the MEMS structure 200, as shown in FIG. 11, which will be elaborated below. A method of forming the stop layer 108 includes, for instance, forming a stop material layer on the dielectric layer 106 and patterning the stop material layer through performing a lithography and etching process. The stop material layer may be, for example, SiN, silicon oxynitride (SiON), silicon oxycarbide (SiOC), silicon carbide (SiC), or a combination thereof, and the stop material layer may be formed by performing a CVD process, for example. In an embodiment of the invention, a thickness of the stop layer 108 may be 50 nm to 200 nm, for instance.

With reference to FIG. 1C, a conductive layer 110 is formed on the stop layer 108. The conductive layer 110 is located on the stop layer 108. A method of forming the conductive layer 110 includes, for instance, forming a conductive material layer on the stop layer 108 and patterning the conductive material layer through performing a lithography and etching process. A material of the conductive material layer may be, for instance, doped polysilicon, undoped polysilicon, single-crystalline silicon, or a combination thereof, and the conductive material layer may be formed by performing a CVD process, for instance. A dielectric layer 112 is then formed on the substrate 100. The dielectric layer 112 covers a surface of the conductive layer 110, a surface of the stop layer 108, and a surface of the dielectric layer 106. A material of the dielectric layer 112 is, for instance, SiO, SiN, or a combination thereof, and a method of forming the dielectric layer 112 includes, for instance, a CVD method, a thermal oxidation method, and so forth.

With reference to FIG. 1D, a contact opening 10 is formed in the first region R1, and contact openings 20 and 30 and a bump opening 40 are formed in the second region R2. The bump opening 40 is located between the contact openings 20 and 30. In an embodiment of the invention, the contact openings 10, 20, and 30 and the bump opening 40 may be formed by performing a patterning process for three times, and the contact openings 10 and 20 may be formed by performing one patterning process. Specifically, a first lithography and etching process is performed to form the contact opening 10 in the dielectric layer 106 and the dielectric layer 112 in the first region R1 and form the contact opening 20 in the dielectric layer 106, the stop layer 108, and the dielectric layer 112 in the second region R2; here, the contact opening 10 exposes one surface of the conductive layer 104, and the contact opening 20 exposes another surface of the conductive layer 104. A second lithography and etching process is performed to form the contact opening 30 in the dielectric layer 112 in the second region R2, so as to expose a surface of the conductive layer 110. A third lithography and etching process is performed to form the bump opening 40 in the dielectric layer 112 in the second region R2.

With reference to FIG. 1E, an MEMS structure 200 is formed on the dielectric layer 112. The MEMS structure 200 has a plurality of cavities 202a-202g. Specifically, an MEMS structure material layer (not shown) is formed on the dielectric layer 112, and the MEMS structure material layer fills the contact openings 10, 20, and 30 and the bump opening 40, respectively, so as to form contact holes 10a, 20a, and 30a and a bump 40a. The MEMS structure material layer is then patterned, so as to form the cavities 202a-202g in the MEMS structure material layer. The cavities 202a-202g respectively expose the surface of the dielectric layer 112. Here, the cavities 202a-202g are neither overlapped with the contact holes 10a, 20a, and 30a nor overlapped with the bump 40a. The cavities 202a and 202b are located in the MEMS structure 200 in the first region R1, and the cavities 202c-202g are located in the MEMS structure 200 in the second region R2. The cavities 202a-202g respectively define the MEMS structures 200a-200h. In the present embodiment, the MEMS structure 200b is electrically connected to the MEMS structure 200d through the contact window 10a, the conductive layer 104, and the contact window 20a. The MEMS structure 200f is electrically connected to the conductive layer 110 through the contact window 30a. In an embodiment of the invention, the MEMS structures 200d and 200f may serve as anchors of the MEMS device having the MEMS structures 200d and 200f. The MEMS structure 200e located between the MEMS structures 200d and 200f may serve as movable components of the MEMS device having the MEMS structure 200e. A material of the MEMS structure 200 may include, for instance, doped polysilicon, undoped polysilicon, single-crystalline silicon, or a combination thereof, and the MEMS structure 200 may be formed by performing a CVD process, for instance. In an embodiment of the invention, a thickness of the MEMS structure 200 may be 6 μm to 9 μm, for instance. A distance from the bottom surface of the MEMS structure 200 to the top surface of the stop layer 108 is 2 μm to 3 μm, for instance. Said distance may be considered as the mechanical movement space of the MEMS structure 200e (i.e., the movable component) according to the present embodiment of the invention. Although the MEMS structure 200 shown in FIG. 1E is equipped with a plurality of cavities 202a-202g, the invention is not limited thereto. In an embodiment of the invention, the MEMS structure may have at least one cavity.

With reference to FIG. 1F, the cavities 202a-202g are filled with a dielectric layer 204. In the present embodiment, the dielectric layer 204 may be considered as a first dielectric layer. Particularly, a dielectric material layer (not shown) is formed on the MEMS structure 200, and the dielectric material layer fills the cavities 202a-202g. The dielectric material layer is then patterned, so as to form a plurality of contact openings 206 in the dielectric layer 204 in the first region R1. A material of the dielectric layer 204 includes borophosphosilicate glass (BPSG), phosphosilicate glass (PSG), spin-on glass (SOG), high density plasma-oxide (HDP-oxide), or a combination thereof, and the dielectric layer 204 may be formed by performing a CVD process, for instance. Note that the material of the dielectric layer 204 is not limited to those described above; any material characterized by high gap-filling capability falls within the scope of protection as provided herein.

A cap layer 208 is formed on the dielectric layer 204. A method of forming the cap layer 208 includes forming a cap material layer (not shown) on the dielectric layer 204. The cap material layer fills the contact openings 206 to form a plurality of contact holes 206a in the dielectric layer 204 in the first region R1. The cap material layer is then patterned to form two openings 50a and 50b as well as a plurality of release holes 210 in the cap layer 208. The openings 50a and 50b are located in the cap layer 208 in the first region R1 and at two sides of the contact holes 206a. That is, the contact holes 206a are located between the openings 50a and 50b. The release holes 210 are located in the cap layer 208 in the second region R2 and expose surfaces of the dielectric layer 204. In the present embodiment, the release holes 210 and the cavities 202c-202f may be partially overlapped. The dielectric material layer filling the cavities 202c-202f may be considered as sacrificial structures which are subsequently removed in the release process of the MEMS structure 200, as shown in FIG. 1I, which will be elaborated hereinafter. A material of the cap layer 208 includes doped polysilicon, undoped polysilicon, single-crystalline silicon, or a combination thereof, and the cap layer 208 may be formed by performing a CVD process, for example. A dielectric layer 212 is then formed on the cap layer 208. In the present embodiment, the dielectric layer 212 may be considered as a second dielectric layer. The dielectric layer 212 fills the openings 50a and 50b and the release holes 210. A material of the dielectric layer 212 is, for instance, SiO, SiN, or a combination thereof, and a method of forming the dielectric layer 212 includes, for instance, a CVD method, a thermal oxidation method, and so forth.

With reference to FIG. 1G, a planarization process is formed on the dielectric layer 212 to form a planarized dielectric layer 212a. In the present embodiment, the planarization process is, for instance, a CMP process, an etch back process, or a combination thereof. Besides, after the planarization process is performed, a thinning process may be performed on a rear surface S2 of the substrate 100. The thinning process may contribute to the reduction of the thickness of the MEMS device, and the resultant MEMS device may be characterized by compactness and light weight. During the planarization process or the thinning process, the dielectric layer 204 fills all of the cavities 202a-202g of the MEMS structure 200, so as to provide sufficient mechanical strength to the MEMS structure 200. Compared to the conventional MEMS structure, the MEMS structure 200 provided in the present embodiment has the mechanical strength enough to resist the pressure resulting from the planarization process and the thinning process, such that damages to the MEMS structure 200 or collapse of the MEMS structure 200 can be avoided. Accordingly, according to an embodiment of the invention, the yield of the MEMS device can be improved, and the product having the MEMS device can have the enhanced reliability. In the present embodiment, the yield of the MEMS device can reach 50%-80%.

With reference to FIG. 1H, a conductive pad 214 is formed in the first region R1, and the conductive pad 214 is in contact with the cap layer 208. To be specific, the planarized dielectric layer 212a is patterned to form an opening 60. The opening 60 exposes a portion of the surface of the cap layer 208 in the first region R1. A conductive material layer (not shown) is then formed on the planarized dielectric layer 212a and the cap layer 208, and the conductive material layer fills the opening 60. The conductive material layer is patterned, so as to form the conductive pad 214 on the cap layer 208 in the first region R1. A material of the conductive material layer includes copper, aluminum, gold, silver, or a combination thereof, and the conductive material layer can be formed by performing a physical vapor deposition (PVD) process or a CVD process. The conductive pad 214 may be electrically connected to the MEMS structure 200d through the cap layer 208, the contact holes 206a, the MEMS structure 200b, the contact window 10a, the conductive layer 104, and the contact window 20a. Hence, according to the present embodiment, power may be supplied to the conductive pad 214, so as to control the operation of the MEMS structures 200d, 200e, and 200f.

A passivation layer 216 is then formed on the conductive pad 214 and the planarized dielectric layer 212a. The passivation layer 216 has an opening 70. The opening 70 exposes the planarized dielectric layer 212a on the release holes 210. A method of forming the passivation layer 216 includes forming a passivation material layer on the substrate 100, for instance. A lithography and etching process is then performed to pattern the passivation material layer. The passivation material layer may be a dielectric material or a semiconductor material, e.g., SiN, TiN, amorphous silicon, or a combination thereof, and the passivation material layer may be formed by performing a CVD process, for instance.

As shown in FIG. 1I, a release process is performed to remove the planarized dielectric layer 212a below the opening 70 and the dielectric layers 204 and 112 below the release holes 210, so as to release the MEMS structures 200d, 200e, and 200f. An etching process may serves as the release process. In an embodiment of the invention, the etching process includes a vapor phase etching process, a liquid-phase etching process, or a combination thereof. During the etching process, the stop layer 108 may serve as an etch stop layer, so as to further remove the dielectric layer 112 below the MEMS structures 200d, 200e, and 200f and form the cavities 220, 222, and 224. The cavity 220 communicates with the cavity 202c; the cavity 222 communicates with the cavities 202d and 202e, and the cavity 224 communicates with the cavity 202f. That is, the etching process may serve as the release process of the MEMS structures 200d, 200e, and 200f; by removing parts of the dielectric layers 112, 204, and 212, a movable component in the MEMS structure 200 may move in a mechanical manner in the cavities 202c-200f and the cavities 220-224. In the present embodiment, the moveable component may be the MEMS structure 200e; however, the invention is not limited thereto, and modifications may be made according to design requirements.

With reference to FIG. 1J, a sealing layer 218 is formed on the MEMS structure 200. Specifically, a sealing material layer (not shown) is formed on the passivation layer 216. The sealing material layer fills the opening 70 and the release holes 210. According to an embodiment of the invention, a material of the sealing layer 218 includes polymer, SiN, SiO, or a combination thereof. The sealing material layer and the passivation layer 216 are then patterned to form an opening 80. The opening 80 exposes a portion of a surface of the conductive pad 214. The passivation layer 216 covers a portion of the conductive pad 214; besides, the passivation layer 216 is located between the sealing layer 218 and the conductive pad 214 and between the sealing layer 218 and the planarized dielectric layer 212a. The sealing layer 218 may protect the underlying MEMS structure 200 from being affected by ambient temperature and moisture and further prevent erosion of the MEMS structure 200 or damages to the MEMS structure 200. In addition, a wire bonding step, an eutectic bonding step, a soldering step, and a flip chip bonding step in the subsequent packaging process may be performed on the surface of the conductive pad 214 exposed by the opening 80.

As shown in FIG. 1J, in an embodiment of the invention, an MEMS device 300 that includes the substrate 100, an MEMS structure 310, a periphery structure 320, the cap layer 208, the conductive pad 214, and the sealing layer 218 is provided. The MEMS structure 310 is located on the substrate 100. The MEMS structure 310 has a plurality of cavities 202c-202f. The cavities 202c-202f divide the MEMS structure 310 into a plurality of MEMS structures 200d, 200e, and 200f. Although the MEMS structure 310 shown in FIG. 1J is equipped with a plurality of cavities 202c-202f, the invention is not limited thereto. In an embodiment of the invention, the MEMS structure may have at least one cavity. In the present embodiment of the invention, the MEMS structures 200d and 200f, for instance, may serve as anchors of the MEMS device 300 having the MEMS structures 200d and 200f, and the MEMS structure 200e, for instance, may serve as a movable component of the MEMS device 300 having the MEMS structure 200e. The MEMS structure 200e may move in a mechanical manner in the cavities 202c-202f and in the cavities 220-224. The cap layer 208 is located on the MEMS structure 310 and the periphery structure 320. The cap layer 208 has a plurality of release holes 210. The release holes 210 are located on the cavities 202c-202f. The sealing layer 218 is located on the MEMS structure 310 and the periphery structure 320. The sealing layer 218 can protect the underlying MEMS structure 310 from being affected by surroundings.

The conductive pad 214 and the periphery structure 320 are located on the substrate 100 at one side of the MEMS structure 310. The conductive pad 214 is located on the cap layer 208 in the periphery structure 320. The conductive pad 214 may be electrically connected to the periphery structure 320 through the cap layer 208 and the contact holes 206a. The periphery structure 320 may be electrically connected to the MEMS structure 310 through the contact window 10a, the conductive layer 104, and the contact window 20a. That is, the conductive pad 214 and the periphery structure 320 are electrically connected to the MEMS structure 310. The subsequent packaging process may be performed on the conductive pad 214 which is not covered by the sealing layer 218. In addition, the MEMS device 300 further includes the passivation layer 216 that covers a portion of the conductive pad 214; besides, the passivation layer 216 is located between the sealing layer 218 and the conductive pad 214 and between the sealing layer 218 and the planarized dielectric layer 212a.

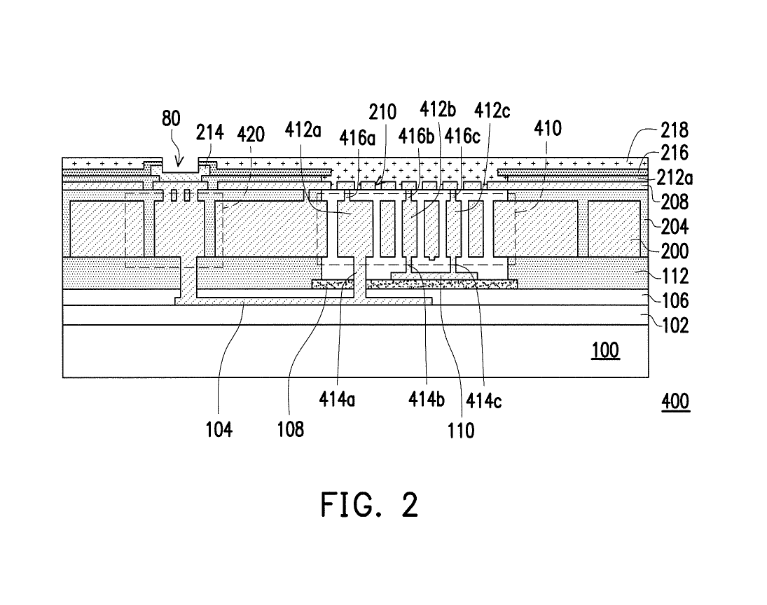

FIG. 2 is a schematic cross-sectional view of an MEMS device according to another embodiment of the invention.

With reference to FIG. 2, the MEMS device 400 shown in FIG. 2 is similar to the MEMS device 300 shown in FIG. 1J, and the difference therebetween lies in that the MEMS device 400 shown in FIG. 2 further includes a support structure 412a. Specifically, the support structure 412a is interleaved in the MEMS structure 410, connected to the conductive layer 104 through the contact window 414a, and connected to the cap layer 208 through the contact window 416a, so as to enhance the mechanical strength of the MEMS structure 410 and the cap layer 208. In another embodiment of the invention, the MEMS device 400 may further include a support structure 412b, a support structure 412c, or both of the two support structures 412b and 412c. Particularly, the support structure 412b is connected to the conductive layer 110 through the contact window 414b and connected to the cap layer 208 through the contact window 416b. The support structure 412c is connected to the conductive layer 110 through the contact window 414c and connected to the cap layer 208 through the contact window 416c. Hence, after the sealing layer 218 is formed, and while a wafer dicing process and a packaging process are performed on the MEMS device 400, the support structures 412a-412c may further enhance the mechanical strength of the MEMS structure 410 and prevent damages to or collapse of the MEMS structure 410.

To sum up, an in-situ cap layer in the MEMS device described herein allows the chip area to be reduced, and the costs can be lowered down accordingly. From another perspective, compared to the ex-situ cap, the in-situ cap layer described herein is conducive to the reduction of the height and the thickness of the resultant MEMS device, such that the flexibility of the packaging process can be enhanced. Moreover, in an embodiment of the invention, after the planarization process and the thinning process are performed, the MEMS structure is released. Prior to the planarization process, the cavities of the MEMS structure provided herein have the dielectric layer therein, and the dielectric layer contributes to the improvement of the mechanical strength of the MEMS structure, so as to resist the pressure resulting from the planarization process and the thinning process as well as prevent damages to the MEMS structure or collapse of the MEMS structure. Accordingly, the yield of the resultant MEMS device can be improved, and the product having the MEMS device can have the enhanced reliability. In another aspect, the MEMS device provided herein further includes a plurality of support structures. The support structures are alternately arranged in the MEMS structure and may further enhance the mechanical strength of the MEMS structure and the cap layer; as a result, while a wafer dicing process and a packaging process are subsequently performed on the MEMS structure, the MEMS structure can be prevented from damages or collapse.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. A method for fabricating a micro-electro-mechanical system device, the method comprising:
forming a micro-electro-mechanical system structure on a substrate, the micro-electro-mechanical system structure having at least one cavity therein;
forming a first dielectric layer covering the micro-electro-mechanical system structure, the first dielectric layer filling the at least one cavity;
forming a cap layer on the first dielectric layer, the cap layer having a plurality of release holes, wherein the release holes are located on the micro-electro-mechanical system structure;
forming a second dielectric layer on the cap layer, the second dielectric layer filling the release holes;
performing a planarization process on the second dielectric layer to form a planarized second dielectric layer, wherein the first dielectric layer is still located on the micro-electro-mechanical system structure and in the at least one cavity; and
performing a release process to remove the planarized second dielectric layer above the release holes and the first dielectric layer below the release holes.

2. The method according to claim 1, further comprising forming a stop layer on the substrate correspondingly located below the micro-electro-mechanical system structure before the micro-electro-mechanical system structure is formed.

3. The method according to claim 1, further comprising forming a plurality of support structures in the micro-electro-mechanical system structure, the support structures being respectively connected to the cap layer and a conductive layer below the micro-electro-mechanical system structure.

4. The method according to claim 1, wherein the release process comprises an etching process, and the etching process comprises a vapor phase etching process, a liquid-phase etching process, or a combination thereof.

5. The method according to claim 1, further comprising forming a sealing layer after the release process is performed, the sealing layer covering the micro-electro-mechanical system structure.

6. The method according to claim 1, further comprising forming a conductive pad on the planarized second dielectric layer before the release process is performed, the conductive pad being connected to the cap layer.

7. The method according to claim 6, further comprising forming a passivation layer on the planarized second dielectric layer after the conductive pad is formed, the passivation layer covering a portion of the conductive pad and having an opening, the opening exposing parts of the planarized second dielectric layer on the release holes.

8. The method according to claim 7, wherein a material of the passivation layer comprises silicon nitride, titanium nitride, amorphous silicon, or a combination thereof.

9. The method according to claim 1, wherein the planarization process comprises a chemical-mechanical polishing process, an etch back process, or a combination thereof.

10. A micro-electro-mechanical system device comprising:
a micro-electro-mechanical system structure located on a substrate, the micro-electro-mechanical system structure having at least one cavity therein;
a periphery structure located on the substrate at one side of the micro-electro-mechanical system structure;
a cap layer located on the micro-electro-mechanical system structure and the periphery structure;
a conductive pad located on the cap layer in the periphery structure and electrically connected to the periphery structure through the cap layer; and
a sealing layer covering the micro-electro-mechanical system structure and a portion of the conductive pad.

11. The micro-electro-mechanical system device according to claim 10, further comprising a plurality of support structures in the micro-electro-mechanical system structure, the support structures being respectively connected to the cap layer and a conductive layer below the micro-electro-mechanical system structure.

12. The micro-electro-mechanical system device according to claim 11, wherein a material of the support structures comprises doped polysilicon, undoped polysilicon, single-crystalline silicon, or a combination thereof.

13. The micro-electro-mechanical system device according to claim 10, further comprising a passivation layer covering a portion of the conductive pad, the passivation layer being located between the conductive pad and the sealing layer.

14. The micro-electro-mechanical system device according to claim 13, wherein a material of the passivation layer comprises silicon nitride, titanium nitride, amorphous silicon, or a combination thereof.

15. The micro-electro-mechanical system device according to claim 10, wherein a material of the micro-electro-mechanical system structure comprises doped polysilicon, undoped polysilicon, single-crystalline silicon, or a combination thereof.

16. The micro-electro-mechanical system device according to claim 10, wherein a material of the cap layer comprises doped polysilicon, undoped polysilicon, single-crystalline silicon, or a combination thereof.

17. The micro-electro-mechanical system device according to claim 10, wherein a material of the sealing layer comprises polymer, silicon nitride, silicon oxide, or a combination thereof.

18. A method for fabricating a micro-electro-mechanical system device, the method comprising:
sequentially forming a cap layer and a dielectric layer on a micro-electro-mechanical system structure, the micro-electro-mechanical system structure having a plurality of sacrificial structures therein, the cap layer having a plurality of release holes, wherein the release holes are located on the sacrificial structures;
performing a planarization process on the dielectric layer, wherein the sacrificial structures are located in the micro-electro-mechanical system structure; and
removing the sacrificial structures to form at least one cavity in the micro-electro-mechanical system structure.

19. The method according to claim 18, further comprising forming a sealing layer on the cap layer, the sealing layer filling the release holes of the cap layer to seal the micro-electro-mechanical system structure.

20. The method according to claim 18, further comprising forming a plurality of support structures in the micro-electro-mechanical system structure.
